(19) United States
(12) Patent Application Publication
(10) Pub. No.: US 2015/0371851 A1
(43) Pub. Date: Dec. 24, 2015

(54) AMORPHOUS CARBON DEPOSITION PROCESS USING DUAL RF BIAS FREQUENCY APPLICATIONS

(71) Applicant: APPLIED MATERIALS, INC., Santa Clara, CA (US)

(72) Inventors: Kwangduk Douglas LEE, Redwood City, CA (US); Wonseok LEE, Paju-Si (KR); Martin Jay SEAMONS, San Jose, CA (US)

(21) Appl. No.: 14/655,404

(22) PCT Filed: Jan. 21, 2014
(86) PCT No.: PCT/US14/12379

§ 371 Date: Jun. 25, 2015

Related U.S. Application Data
(60) Provisional application No. 61/792,559, filed on Mar. 15, 2013.

(51) Int. Cl. H01L 21/033; H01L 21/308; H01L 21/311

(52) U.S. Cl. CPC H01L 21/0332; H01L 21/31144; H01L 21/3081

(57) ABSTRACT

Methods for forming an amorphous carbon layer with desired film mechanical strength low film stress as well as optical film properties are provided. In one embodiment, a method of forming an amorphous carbon layer includes forming a plasma of a deposition gas mixture including a hydrocarbon gas supplied in a processing chamber by application of a RF source power, applying a low frequency RF bias power and a high frequency RF bias power to a first electrode disposed in the processing chamber, controlling a power ratio of the high frequency to the low frequency RF bias power, and forming an amorphous carbon layer on a substrate disposed in the processing chamber.

### BACKGROUND

1. Field of the Invention

The present invention relates to the fabrication of integrated circuits and to a process for forming a hardmask layer with high etching selectivity and good mechanical strength on a substrate. More specifically, the invention relates to a process for manufacturing an amorphous carbon layer with high etching selectivity, good mechanical strength and low stress on a substrate for semiconductor applications.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures having small critical dimensions and high aspect ratios has become increasingly difficult. For example, the thickness of the energy sensitive resist has been reduced in order to control pattern resolution. Such thin resist layers (e.g., less than about 2000 Å) can be insufficient to mask underlying material layers during the pattern transfer step due to attack by the chemical etchant. An intermediate layer (e.g., silicon oxynitride, silicon carbine or carbon film), called a hardmask layer, is often used between the energy sensitive resist layer and the underlying material layers to facilitate pattern transfer because of its greater resistance to chemical etchants. When etching materials to form structures having aspect ratios greater than about 5:1 and/or critical dimensional less than about 50 nm, the hardmask layer utilized to transfer patterns to the materials is exposed to aggressive etchants for a significant period of time. After a long period of exposure to the aggressive etchants, the hardmask layer without sufficient etching resistance may be change, resulting in inaccurate pattern transfer and loss of dimensional control.

Furthermore, the similarity of the materials selected for the hardmask layer and the adjacent layers disposed in the film stack may also result in similar etch properties therebetween, thereby resulting in poor selectivity during etching. Poor selectivity between the hardmask layer and adjacent layers may result in non-uniform, tapered and deformed profile of the hardmask layer, thereby leading to poor pattern transfer and failure of accurate structure dimension control.

Additionally, stress in the deposited film and/or hardmask layer may also result in stress induced line edge bending and/or line breakage. Overly high stress of the hardmask layer may cause substrate bow that result in substrate chucking/dechucking problems. Furthermore, high stress of the hardmask layer also result in compressive film structure of the hardmask layer which may lead to depth-of-focus problems during a lithography exposure process, thereby adversely affecting pattern transfer accuracy in the subsequent processes.

Therefore, there is a need in the art for an improved hardmask layer with desired film properties for subsequent lithography and etching processes.

### SUMMARY

Methods for forming an amorphous carbon layer with desired film mechanical strength low film stress as well as optical film properties are provided. In one embodiment, a method of forming an amorphous carbon layer includes forming a plasma of a deposition gas mixture including a hydrocarbon gas supplied in a processing chamber by application of a RF source power, applying a low frequency RF bias power and a high frequency RF bias power to a first electrode disposed in the processing chamber, controlling a power ratio of the high frequency to the low frequency RF bias power, and forming an amorphous carbon layer on a substrate disposed in the processing chamber.

In another embodiment, a method of forming an amorphous carbon layer includes forming a plasma in a deposition gas mixture including a hydrocarbon gas supplied in a processing chamber having a substrate disposed therein, applying a low frequency and a high frequency RF bias powers at a ratio between about 1:10 and about 10:1 to a first electrode disposed in the processing chamber, and forming an amorphous carbon layer on the substrate disposed in the processing chamber, the amorphous carbon layer having a density greater than 1.6 g/cc and a stress less than 800 mega-pascal (MPa) compressive.

In yet another embodiment, a method of an amorphous carbon layer includes providing a substrate having a material layer in a processing chamber, forming a plasma in a deposition gas mixture in the processing chamber, applying a low frequency and a high frequency RF bias powers at a ratio between about 1:10 and about 10:1 to an electrode disposed in the processing chamber, forming an amorphous carbon layer on a material layer disposed on a positioned in the processing chamber, and etching the material layer using the amorphous carbon layer as a hardmask layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic illustration of a deposition apparatus suitable for practice one embodiment of the present invention;

FIG. 2 depicts another embodiment of schematic illustration of a deposition apparatus suitable for practice one embodiment of the present invention:

FIG. 3 depicts a flow process diagram of a film formation process according to one embodiment of the present invention; and

FIGS. 4A-4B depict a sequence of schematic cross-sectional views of a substrate structure incorporating an amorphous carbon layer formed on the substrate according to the method of FIG. 3.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method for forming an amorphous carbon layer with desired film properties, such as film transparency, mechanical strength and low stress. In one embodiment, the amorphous carbon layer is suitable for use as a hardmask layer during an etching process. The amorphous carbon layer with desired film properties may be obtained by applying dual frequency RF bias power during the amorphous carbon layer deposition process. Dual frequency RF bias power utilized during the amorphous carbon deposition process may alter bonding structures and bonding energy of the carbon bonds, thereby efficiently maintaining the amorphous carbon layer stress at a low level. Optical film properties, such as desired range of index of refraction (n) and the absorption coefficient (k) advantageous for photolithographic patterning processes, and other film properties may still be remained substantially at similar desired ranges for the amorphous carbon layer formed by the dual frequency RF bias power process.

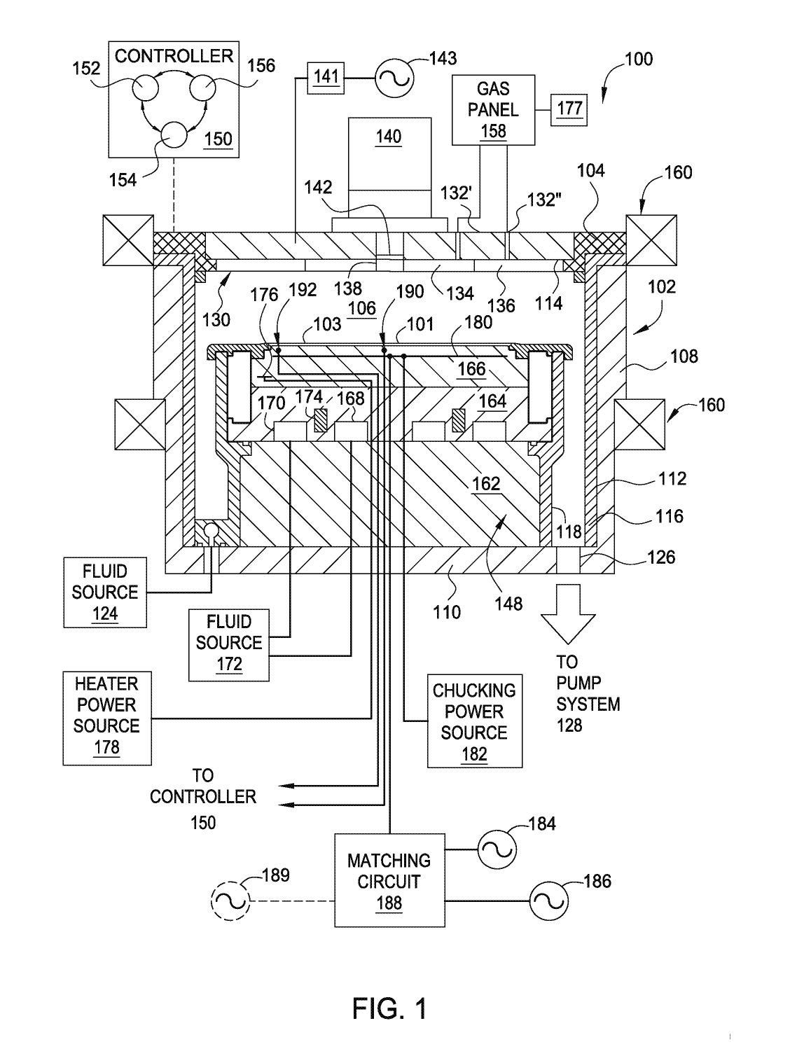

FIG. 1 is a sectional view of one embodiment of a processing chamber 100 suitable for depositing an amorphous carbon layer using dual frequency RF bias power. Suitable processing chambers that may be adapted for use with the teachings disclosed herein include, for example, a modified ENABLER® processing chamber available from Applied Materials, Inc. of Santa Clara, Calif. Although the processing chamber 100 is shown including a plurality of features that enable an amorphous carbon layer deposition process using dual frequency RF bias power, it is contemplated that other processing chambers may be adapted to benefit from one or more of the inventive features disclosed herein.

The processing chamber 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate access port (not shown) is generally defined in a side wall 108 and a selectively sealed by a slit valve to facilitate entry and egress of a substrate 101 from the processing chamber 100. An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In one embodiment, the pump system 128 maintains the pressure inside the interior volume 106 at operating pressures typically between about 10 mTorr to about 20 Torr.

The lid 104 is sealingly supported on the sidewall 108 of the chamber body 102. The lid 104 may be opened to allow excess to the interior volume 106 of the processing chamber 100. The lid 104 includes a window 142 that facilitates optical process monitoring. In one embodiment, the window 142 is comprised of quartz or other suitable material that is transmissive to a signal utilized by an optical monitoring system 140.

The optical monitoring system 140 is positioned to view at least one of the interior volume 106 of the chamber body 102 and/or the substrate 101 positioned on a substrate support assembly 148 through the window 142. In one embodiment, the optical monitoring system 140 is coupled to the lid 104 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

A gas panel 158 is coupled to the processing chamber 100 to provide process and/or cleaning gases to the interior volume 106. In the embodiment depicted in FIG. 1, inlet ports 132′, 132″ are provided in the lid 104 to allow gases to be delivered from the gas panel 158 to the interior volume 106 of the processing chamber 100.

A showerhead assembly 130 is coupled to an interior surface 114 of the lid 104, The showerhead assembly 130 includes a plurality of apertures that allow the gases flowing through the showerhead assembly 130 from the inlet port 132 into the interior volume 106 of the processing chamber 100 in a predefined distribution across the surface of the substrate 101 being processed in the chamber 100.

A remote plasma source 177 may be coupled to the gas panel 158 to facilitate dissociating gas mixture from a remote plasma prior to entering into the interior volume 106 for processing. A RF source power 143 is coupled through a matching network 141 to the showerhead assembly 130. The RF source power 143 typically is capable of producing up to about 3000 W at a tunable frequency in a range from about 50 kHz to about 13.56 MHz.

The showerhead assembly 130 additionally includes a region transmissive to an optical metrology signal. The optically transmissive region or passage 138 is suitable for allowing the optical monitoring system 140 to view the interior volume 106 and/or substrate 101 positioned on the substrate support assembly 148. The passage 138 may be a material, an aperture or plurality of apertures formed or disposed in the showerhead assembly 130 that is substantially transmissive to the wavelengths of energy generated by, and reflected back to, the optical measuring system 140. In one embodiment, the passage 138 includes a window 142 to prevent gas leakage that the passage 138. The window 142 may be a sapphire plate, quartz plate or other suitable material. The window 142 may alternatively be disposed in the lid 104.

In one embodiment, the showerhead assembly 130 is configured with a plurality of zones that allow for separate control of gas flowing into the interior volume 106 of the processing chamber 100. In the embodiment FIG. 1, the showerhead assembly 130 as an inner zone 134 and an outer zone 136 that are separately coupled to the gas panel 158 through separate inlets 132.

The substrate support assembly 148 is disposed in the interior volume 106 of the processing chamber 100 below the gas distribution assembly 130. The substrate support assembly 148 holds the substrate 101 during processing. The substrate support assembly 148 generally includes a plurality of lift pins (not shown) disposed therethrough that are configured to lift the substrate 101 from the substrate support assembly 148 and facilitate exchange of the substrate 101 with a robot (not shown) in a conventional manner. An inner liner 118 may closely circumscribe the periphery of the substrate support assembly 148.

In one embodiment, the substrate support assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among other, to the base 164 and the electrostatic chuck 166. The electrostatic chuck 166 comprises at least one clamping electrode 180 for retaining a substrate 101 below showerhead assembly 130. The electrostatic chuck 180 is driven by a chucking power source 182 to develop an electrostatic force that holds the substrate 101 to the chuck surface, as is conventionally known. Alternatively, the substrate 101 may be retained to the substrate support assembly 148 by clamping, vacuum or gravity.

At least one of the base 164 or electrostatic chuck 166 may include at least one optional embedded heater 176, at least one optional embedded isolator 174 and a plurality of conduits 168, 170 to control the lateral temperature profile of the substrate support assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the electrostatic chuck 166. The temperature of the electrostatic chuck 166 and the base 164 may be monitored using a plurality of temperature sensors 190, 192. The electrostatic chuck 166 may further comprise a plurality of gas passages (not shown), such as grooves, that are formed in a substrate supporting surface of the chuck 166 and fluidly coupled to a source of a heat transfer for backside) gas, such as He. In operation, the backside gas is provided at controlled pressure into the gas passages to enhance the heat transfer between the electrostatic chuck 166 and the substrate 101.

In one embodiment, the substrate support assembly 148 is configured as a cathode and includes an electrode 180 that is coupled to a plurality of RF power bias sources 184, 186. The RF bias power sources 184, 186 are coupled between the electrode 180 disposed in the substrate support assembly 148 and another electrode, such as the showerhead assembly 130 or ceiling 104 of the chamber body 102. The RF bias power excites and sustains a plasma discharge formed from the gases disposed in the processing region of the chamber body 102.

In the embodiment depicted in FIG. 1, the dual RF bias power sources 184, 186 are coupled to the electrode 180 disposed in the substrate support assembly 148 through a matching circuit 188. The signal generated by the RF bias power 184, 186 is delivered through matching circuit 188 to the substrate support assembly 148 through a single feed to ionize the gas mixture provided in the plasma processing chamber 100, thereby providing ion energy necessary for performing a deposition or other plasma enhanced process. The RF bias power sources 184, 186 are generally capable of producing an RF signal having a frequency of from about 50 kHz to about 200 MHz and a power between about 0 Watts and about 5000 Watts. An additional bias power source 189 may be coupled to the electrode 180 to control the characteristics of the plasma.

In one mode of operation, the substrate 101 is disposed on the substrate support assembly 148 in the plasma processing chamber 100. A process gas and/or gas mixture is introduced into the chamber body 102 through the showerhead assembly 130 from the gas panel 158. Furthermore, additional gases may be supplied from the remote plasma source 177 through the showerhead assembly 130 to the processing chamber 100. A vacuum pumping system 128 maintains the pressure inside the chamber body 102 while removing deposition by-products. The vacuum pumping system 128 typically maintains an operating pressure between about 10 mTorr to about 20 Torr.

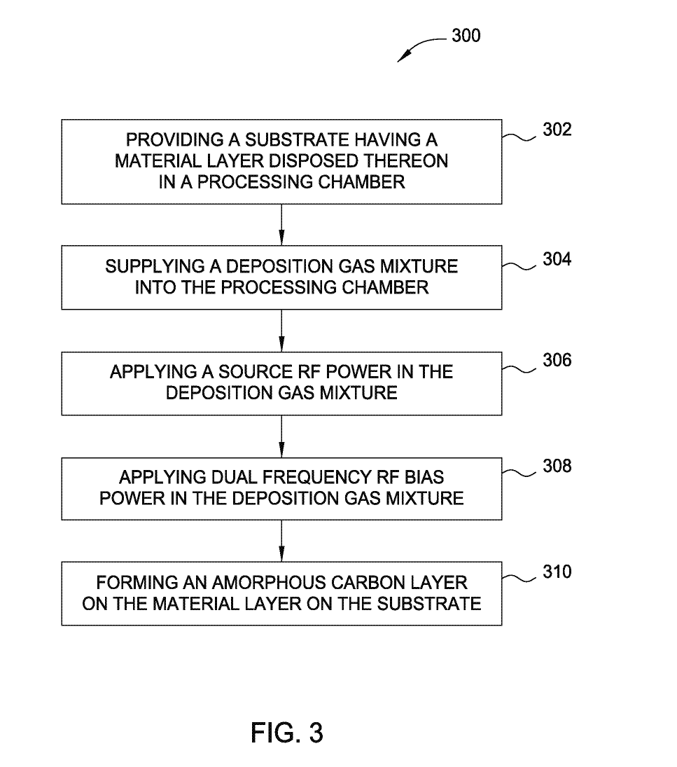

The RF source power 143 and the RF bias power 184, 186 provide RF source and bias power at separate frequencies to the anode and/or cathode through the matching circuit 141 and 188 respectively, thereby providing energy to form the plasma and excite the gas mixture in the chamber body 102 into ions to perform a plasma process, in this example, a deposition process as further described below with reference to FIG. 3.

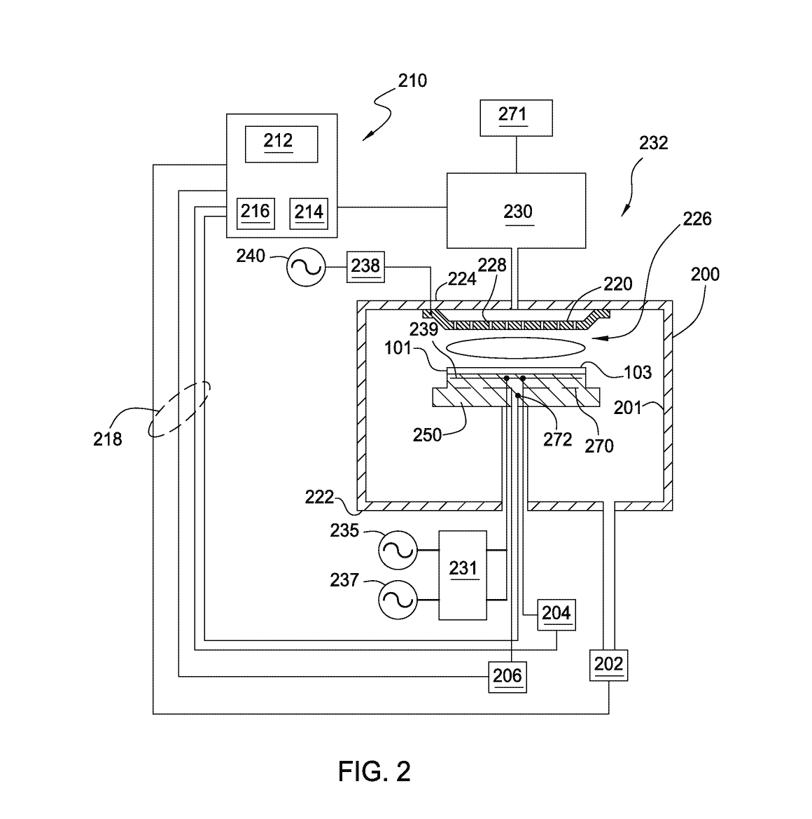

FIG. 2 is a schematic representation of another substrate processing system 232 that can be used to perform amorphous carbon layer deposition in accordance with embodiments of the present invention. Other examples of systems that may be used to practice the invention include CENTURA®, PRECISION 5000® and PRODUCER® deposition systems, all available from Applied Materials Inc., Santa Clara, Calif. It is contemplated that other processing system, including those available from other manufacturers, may be adapted to practice the invention.

The processing system 232 includes a process chamber 200 coupled to a gas panel 230 and a controller 210. The process chamber 200 generally includes a top 224, a side 201 and a bottom wall 222 that define an interior volume 226. A substrate support assembly 250 is provided in the interior volume 226 of the chamber 200. The substrate support assembly 250 may be fabricated from aluminum, ceramic, and other suitable materials. In one embodiment, the substrate support assembly 250 is fabricated by a ceramic material, such as aluminum nitride, which is a material suitable for use in a high temperature environment, such as a plasma process environment, without causing thermal damage to the substrate support assembly 250. The substrate support assembly 250 may be moved in a vertical direction inside the chamber 200 using a lift mechanism (not shown).

The substrate support assembly 250 may include an embedded heater element 270 suitable for controlling the temperature of a substrate 101 supported on the substrate support assembly 250. In one embodiment, the substrate support assembly 250 may be resistively heated by applying an electric current from a power supply 206 to the heater element 270. In one embodiment, the heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thereby maintaining the substrate 101 and the substrate support assembly 250 at a substantially constant temperature during film deposition. The supplied electric current may be adjusted to selectively control the temperature of the substrate support assembly 250 between about 100 degrees Celsius to about 780 degrees Celsius, such as greater than 500 degrees Celsius.

A temperature sensor 272, such as a thermocouple, may be embedded in the substrate support assembly 250 to monitor the temperature of the substrate support assembly 250 in a conventional manner. The measured temperature is used by the controller 210 to control the power supplied to the heating element 270 to maintain the substrate 101 at a desired temperature.

The substrate support assembly 250 comprises at least one clamping electrode 239 for retaining the substrate 101 below showerhead assembly 130. The clamping electrode 239 is driven by a chucking power source 204 to develop an electrostatic force that holds the substrate 101 to the substrate surface, as is conventionally known. Alternatively, the substrate 101 may be retained to the substrate support assembly 250 by clamping, vacuum or gravity.

In one embodiment, the substrate support assembly 250 is configured as a cathode and is coupled to a plurality of RF power bias power 235, 237. RF bias powers 235, 237 are coupled between an electrode 239 disposed in the substrate support assembly 250 and another electrode, such as a showerhead assembly 220. The RF bias power excites and sustains a plasma discharge formed from the gases disposed in the processing chamber 100. In the embodiment depicted in FIG. 2, dual RF bias power sources 235, 237 are coupled to the electrode 239 through a matching circuit 231. The signal generated by the RF bias power sources 235, 237 is delivered through matching circuit 231 to the electrode 239 disposed in the substrate support assembly 250 through a single feed to ionize the gas mixture provided in the plasma processing chamber 200, thereby providing ion energy necessary for performing a deposition or other plasma enhanced process. The RF bias power sources 235, 237 are generally capable of producing an RF signal having a frequency of from about 50 kHz to about 200 MHz and a power between about 0 Watts and about 5000 Watts. It is noted that another optional RF bias or source power may be used to control the characteristics of the plasma.

A vacuum pump 202 is coupled to a port formed in the walls of the chamber 200. The vacuum pump 202 is used to maintain a desired gas pressure in the process chamber 200. The vacuum pump 202 also evacuates post-processing gases and by-products of the process from the chamber 200.

The showerhead assembly 220 having a plurality of apertures 228 is coupled to the top 224 of the process chamber 200 above the substrate support assembly 250. The apertures 228 of the showerhead assembly 220 are utilized to introduce process gases into the chamber 200. The apertures 228 may have different sizes, number, distributions, shape, design, and diameters to facilitate the flow of the various process gases for different process requirements. The showerhead assembly 220 is connected to the gas panel 230 that allows various gases to supply to the interior volume 226 during process. A remote plasma source 271 may be coupled to the gas panel 230 to facilitate dissociating gas mixture from a remote plasma prior to entering into the interior volume 226 for processing. A plasma is formed from the process gas mixture exiting the showerhead assembly 220 to enhance thermal decomposition of the process gases resulting in the deposition of material on a surface 103 of the substrate 101.

The showerhead assembly 220 and substrate support assembly 250 may be formed a pair of spaced apart electrodes in the interior volume 226. One or more RF sources 240, 235, 237 provide a source or bias potential through matching networks 238, 231 respectively to the showerhead assembly 220, or to the substrate support assembly 250 to facilitate generation of a plasma between the showerhead assembly 220 and the substrate support assembly 250. Alternatively, the RF power sources 240, bias power sources 235, 237 and matching network 238, may be coupled to the showerhead assembly 220, substrate support assembly 250, or coupled to both the showerhead assembly 220 and the substrate support assembly 250, or coupled to an antenna (not shown) disposed exterior to the chamber 200 in an alternative arrangement. In one embodiment, the RF source power 240 may provide between about 500 Watts and about 3000 Watts at a frequency of about 50 kHz to about 13.56 MHz.

The controller 210 includes a central processing unit (CPU) 212, a memory 216, and a support circuit 214 utilized to control the process sequence and regulate the gas flows from the gas panel 230. The CPU 212 may be of any form of a general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the control unit 210 and the various components of the processing system 232 are handled through numerous signal cables collectively referred to as signal buses 218, some of which are illustrated in FIG. 2.

The above deposition chambers are described above mainly for illustrative purposes, and other plasma processing chambers may also be employed for practicing embodiments of the invention.

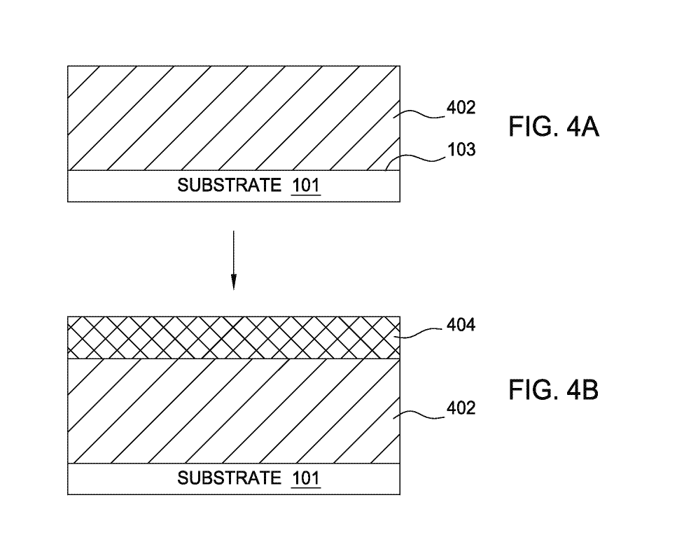

FIG. 3 illustrates a process flow diagram of a method 300 for forming an amorphous carbon layer using dual frequency RF bias power according to one embodiment of the present invention. FIGS. 4A-4B are schematic cross-sectional view illustrating a sequence for forming an amorphous carbon layer using dual frequency RF bias power according to the method 300.

The method 300 begins at step 302 by providing a substrate, such as the substrate 101 depicted in FIGS. 1-2, having a material layer 402 disposed thereon, as shown in FIG. 4A, into a suitable processing chamber, such as the processing chamber 100 depicted in FIG. 1 or alternatively the processing chamber 200 depicted in FIG. 2. The substrate 101 may have a substantially planar surface, an uneven surface, or a substantially planar surface having a structure formed thereon. In one embodiment, the material layer 402 may be a part of a film stack utilized to form a gate structure, a contact structure, an interconnection structure or shallow trench isolation (STI) structure in the front end or back end processes. In embodiments wherein the material layer 402 is not present, the process 300 be directly formed in the substrate 101.

In one embodiment, the material layer 402 maybe a silicon layer utilized to form a gate electrode. In another embodiment, the material layer 402 may include a silicon oxide layer, a silicon oxide layer deposited over a silicon layer. In yet another embodiment, the material layer 402 may include one or more layers of other dielectric materials utilized to fabricate semiconductor devices. Suitable examples of the dielectric layers include silicon oxide, silicon nitride, silicon oxynitride, silicon carbide, or any suitable low-k or porous dielectric material as needed. In still another embodiment, the material layer 302 does not include any metal layers.

At step 304, a deposition gas mixture may be supplied into the processing chamber 100, 132 for the deposition process. The deposition gas mixture includes at least a hydrocarbon gas and an inert gas. In one embodiment, hydrocarbon gas has a formula CₓH_{y}, where x has a range between 1 and 12 and y has a range of between 4 and 26. More specifically, aliphatic hydrocarbons include, for example, alkanes such as methane, ethane, propane, butane, pentane, hexane, heptane, octane, nonane, decane and the like; alkenes such as propene, ethylene, propylene, butylene, pentene, and the like; diener such as hexadiene butadiene, isoprene, pentadiene and the like; alkynes such as acetylene, vinylacetylene and the like. Alicyclic hydrocarbons include, for example, cyclopropane, cyclobutane, cyclopentane, cyclopentadiene, toluene and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3,-tetramethylbutylbenzene, t-butylether, t-butylethylene, methyl-methacrylate, and t-butylfurfurylether may be utilized. Additionally, alpha-terpinene, cymene, 1,1,3,3,-tetramethylbutylbenzene, t-butylether, t-butylethylene, methyl-methacrylate, and t-butylfurfurylether may be selected. In an exemplary embodiment, the hydrocarbon compounds are propene, acetylene, ethylene, propylene, butylenes, toluene, alpha-terpinene. In a particular embodiment, the hydrocarbon compound is propene (C₃H₆) or acetylene.

Alternatively, one or more hydrocarbon gas may be mixed with the hydrocarbon gas in the deposition gas mixture supplied to the process chamber. A mixture of two or more hydrocarbon gas may be used to deposit the amorphous carbon layer.

The inert gas, such as argon (Ar) or helium (He), is supplied with the gas mixture into the process chamber 100, 232. Other carrier gases, such as nitrogen (N₂) and nitric oxide (NO), hydrogen (H₂), ammonia (NH₃), a mixture of hydrogen (H₂) and nitrogen (N₂), or combinations thereof may also be used to control the density and deposition rate of the amorphous carbon layer. The addition of H₂ and/or NH₃ may be used to control the hydrogen ratio (e.g., carbon to hydrogen ratio) of the deposited amorphous carbon layer. The hydrogen ratio present in the amorphous carbon layer provides control over layer properties, such as reflectivity, stress, transparency and density.

In one embodiment, an inert gas, such as argon (Ar) or helium (He) gas, is supplied with the hydrocarbon gas, such as propene (C₃H₆) or acetylene, into the process chamber to deposit the amorphous carbon layer. The inert gas provided in the deposition gas mixture may assist control of the optical and mechanical properties of the as-deposited layer, such as the index of refraction (n) and the absorption coefficient (k), hardness, density and elastic modulus of the amorphous carbon layer to be deposited on the material layer 402.

During deposition, the substrate temperature may be controlled between about 300 degrees Celsius and about 800 degrees Celsius. The hydrocarbon compound, such as propene (C₃H₆), may be supplied in the gas mixture at a rate between about 200 sccm and about 3000 sccm, such as between about 400 sccm and about 2000 sccm. The inert gas, such as Ar gas, may be supplied in the gas mixture at a rate between about 200 sccm and about 10000 sccm, such as about 1200 sccm and about 8000 sccm. A RF source power of between about 400 Watts to about 2000 Watts, such as 450 Watts to about 1000 Watts may be applied to maintain a plasma formed from the gas mixture. The process pressure may be maintained at about 1 Torr to about 20 Torr, such as about 2 Torr and about 12 Torr, for example, about 4 Torr to about 9 Torr. The spacing between the substrate and showerhead may be controlled at about 200 mils to about 1000 mils. It is noted that the hydrocarbon gas may be supplied from a remote plasma source, such as the remote plasma source 177, 271 depisted in FIGS. 1 and 2, to assist dissociating hydrocarbon gas to be supplied for processing. A remote plasma RF power of between about 50 Watts to about 5000 Watts.

In one embodiment, the absorption coefficient (k) of the deposited amorphous carbon layer may be controlled between about 0.2 and about 1.8 at a wavelength about 633 nm, and between about 0.4 and about 1.3 at a wavelength about 243 nm, and between about 0.3 and about 0.6 at a wavelength about 193 nm. The amorphous carbon layer 404 may have a thickness 408 between about 10 nm and about 300 nm.

At step 306, a RF source power may be applied to the processing chamber to form a plasma from the deposition gas mixture. The RF source power utilized to deposit the amorphous carbon layer may be controlled at a range that can provide sufficient on bombardment to dissociate sufficient carbon elements to be formed in the amorphous carbon layer, so that the amorphous carbon layer formed on the substrate 101 may have desired high film density. It is believed that sufficient RF source power utilized during the deposition process may provide higher ion bombardment that may enhance dissociation of the ions from the deposition gas mixture, thereby increasing amounts of carbon elements formed in the amorphous carbon layer, which is believed to directly improve resultant film density.

At step 308, while applying the RF source power to the processing chamber, dual RF frequency bias power may be supplied to the processing chamber to assist forming a plasma in the deposition gas mixture. The dual RF frequency bias power may be applied to an electrode, such as a showerhead assembly or a substrate, or both disposed in the processing chamber. The dual RF frequency bias power may be applied with ratio control in the processing chamber. In the embodiment depicted herein, the dual RF frequency bias power is applied to a cathode, such as the substrate support assembly 148 or 250 depicted in FIG. 1-2 respectively.

In one embodiment, a first RF bias power is selected to generate a bias power at a first frequency of about 2 MHz and the second RF bias power is selected to generate power at a second frequency of about 60 MHz. The RF bias powers provide up to about 3000 Watts of total RF power in a predetermined power ratio for the first bias power to the second bias power of between 1:10 and 10:1. It is believed that the first and the second bias powers provide bias power to the substrate 101 that affect the ion distribution and density formed across the substrate surface. Adjusting the ratio between the first bias power and second bias power as supplied to the processing chamber controls the characteristics and distribution of the plasma. The plasma, having a characteristic defined by the power ratio of the bias powers, facilitates depositing an amorphous carbon layer with adjustable film properties formed on the substrate 101.

It is believed that the first frequency of the first RF bias power provides a broad ion energy distribution (e.g., lower frequency). The second frequency of the second RF bias power provides a peaked, well defined ion energy distribution (e.g., higher frequency). The first frequency is selected such that its cycle time is much larger than the transit time of an ion in the sheath, while the second frequency is selected such that its period approaches or surpasses the transit time of the ion in the sheath. These frequencies are also selected such that when used in conjunction with a third power source provided by an independently driven electrode (e.g., the showerhead assembly), they are not the primary power contributor for plasma ionization and dissociation. The combined applied voltage of the two frequency RF bias is used to control the peak-to-peak sheath voltage as well as the self-biased DC potential that is used for deposition. The mixing of the two bias frequencies is used to tune the energy distribution about this average acceleration generated by this DC potential. Thus, utilizing a plasma enhanced processing chamber with a dual frequency RF bias power, the ion energy distribution within the plasma can be controlled.

In one embodiment, a deposition process window is advantageously widened by mixing a high frequency (e.g., 13.56 MHz, 60 MHz, 162 MHz, or higher) and a low frequency (e.g., 2 MHz or lower frequency) bias RF signal with different mixing ratio in a wide total power range. The ratio of the bias power of the two bias frequencies can be advantageously utilized to control the ion energy distribution and plasma sheath, thereby facilitating the flexibility to control amount of carbon elements generated in the process chamber and the bonding energy as formed. It is believed that higher frequency components have a progressively much more concentrated ion/plasma density while low frequency component may advantageously provide more ion energy with vertical and straight ion profiles. By doing so, film properties, with desired film density along with film stress and film transparency, may be advantageously obtained. Furthermore, as the process window in widened, the bonding energy formed between the carbon elements may be adjusted by selecting different RF bias power with different RF frequencies at different ratio so that a relatively desired stress level of the amorphous carbon layer may be obtained. In one example, when a 50 percent of 2 MHz first RF bias power and a 50 percent 60 MHz second bias power is selected, an effective bias power of about 31 MHz RF bias power may be obtained. By manipulating plasma ion distribution and sheath as generated at different RF bias frequency, a desired film high density as formed in the amorphous carbon layer with desired low stress level may be obtained and balanced.

In one embodiment, a ratio of a first bias power with a first frequency to the second bias power with a second frequency may be applied to the processing chamber at between about 1:10 and 10:1, such as between about 8:1 and about 1:5, for example about 7:1 and about 1:1. The first frequency is a relatively high frequency greater than 10 MHz, such as between about 10.5 MHz and about 200 MHz. The second frequency is a relatively lower frequency less than 8 MHz, such as between about 0.1 MHz and about 7 MHz. The first RF bias power of between about 100 Watts to about 2000 Watts, such as 150 Watts to about 900 Watts may be applied to the processing chamber. The second RF bias power of between about 100 Watts to about 3000 Watts, such as 500 Watts to about 2000 Watts, may be applied to the processing chamber.

At step 310, an amorphous carbon layer 404 with desired film properties may be formed on the substrate 101 under the dual RF bias frequency power deposition process, as shown in FIG. 4B, As discussed above, under dual RF bias frequency along with desired power ratio between the high and low RF bias frequency, film properties, with desired film density along with film stress and film transparency, may be advantageously obtained. In one embodiment, a film density greater than 1.6 g/cc, such as between about 1.7 g/cc and about 2.3 g/cc may be obtained. Furthermore, hydrogen dissociated from the hydrocarbon supplied in the deposition gas mixture is also believed to assist lowering film stress. The hydrogen ions disrupt into the carbon bonding may change the bonding structures and/or the bonding energy of the carbon bonds in the amorphous carbon layer 404. The mount of the hydrogen termination bonds and the extents of any missing or dangling carbon bonds included in the sp3 hybridized carbons or sp2 hybridized carbons affect how tightly these carbon atoms are networked and packed, thus determining film density and stress. It is believed that dual RF frequency bias modulation may place hydrogen atoms at places to reduce sp3 interconnection of carbon atoms, so as to reduce film stress. Therefore, the hydrogen atoms incorporated into the carbon bonds may efficiently maintain a lower stress level of the amorphous carbon layer 404 less than 800 mega-pascal (MPa) compressive, such as between about 800 mega-pascal (MPa) compressive and about 100 mega-pascal (MPa) compressive

Other film properties, such as film transparency, are substantially remained the same. In one embodiment, the absorption coefficient (k) of the hydrogen implanted amorphous carbon layer 406 may be controlled at between about 0.2 and about 1.8 at a wavelength about 633 nm, and between about 0.4 and about 1.3 at a wavelength about 243 nm, and between about 0.3 and about 0.6 at a wavelength about 193 nm.

Thus, a method for forming an amorphous carbon layer with dual RF bias frequency having both desired density and optical film properties with low stress are provided. The method advantageously improves the mechanical properties, such as low stress and high density, of the amorphous carbon layer. The improved mechanical properties of the amorphous carbon layer provides high film selectivity and quality for the subsequent etching process while maintaining desired range of the film flatness and film optical properties, such as index of refraction (n) and the absorption coefficient (k), for the subsequent lithography process.

While the foregoing is directed to embodiments of the present invention, other and further embodiments of the invention may be devised without departing from the basic scope thereof, and the scope thereof is determined by the claims that follow.

1. A method of forming an amorphous carbon layer, comprising:
forming a plasma of a deposition gas mixture including a hydrocarbon gas supplied in a processing chamber by application of a RF source power;
applying a low frequency RF bias power and a high frequency RF bias power to a first electrode disposed in the processing chamber;
controlling a power ratio of the high frequency to the low frequency RF bias power; and
forming an amorphous carbon layer on a substrate disposed in the processing chamber.

2. The method of claim 1, wherein forming a plasma of a deposition gas mixture further comprises:
applying the RF source power to a second electrode located on an opposite side of the substrate relative to the first electrode.

3. The method of claim 1, wherein the first electrode is disposed in a substrate.

4. The method of claim 2, wherein the second electrode is a showerhead assembly.

5. The method of claim 1, wherein a power ratio of the high frequency to the low frequency RF bias power is controlled between about 1:10 and about 10:1.

6. The method of claim 1, wherein the high frequency RF bias power has a frequency greater than 10 MHz.

7. The method of claim 1, wherein the low frequency RF bias power has a frequency less than 8 MHz.

8. The method of claim 1, wherein the high frequency RF bias power is at between about 100 Watts to about 2000 Watts and the low frequency RF bias power is at between about 100 Watts to about 3000 Watts.

9. The method of claim 8, wherein the low frequency RF bias power is at between about 500 Watts to about 2000 Watts.

10. The method of claim 1, wherein the deposition gas mixture including the hydrocarbon gas is supplied from a remote plasma source into the processing chamber.

11. The method of claim 1, wherein a power ratio of the high frequency to the low frequency RF bias power is controlled between about 7:1 and about 1:1.

12. The method of claim 1, wherein the amorphous carbon layer has a film density greater than 1.6 g/cc.

13. The method of claim 1, wherein the amorphous carbon layer has a film stress less than 800 mega-pascal (MPa) compressive.

14. A method of forming an amorphous carbon layer, comprising:
forming a plasma in a deposition gas mixture including a hydrocarbon gas supplied in a processing chamber having a substrate disposed therein;
applying a low frequency and a high frequency RF bias powers at a ratio between about 1:10 and about 10:1 to a first electrode disposed in the processing chamber; and
forming an amorphous carbon layer on the substrate disposed in the processing chamber, the amorphous carbon layer having a density greater than 1.6 g/cc and a stress less than 800 mega-pascal (MPa) compressive.

15. The method of claim 14, wherein the high frequency RF bias power has a frequency greater than 10 MHz and the low frequency RF bias power has a frequency less than 8 MHz.

16. The method of claim 14, wherein forming the plasma in the deposition gas mixture further comprises:
applying a RF source power to a second electrode disposed in the processing chamber.

17. The method of claim 16, wherein the first electrode is a substrate and the second electrode is a showerhead assembly.

18. The method of claim 17, wherein the substrate has a material layer disposed thereon prior to forming the amorphous carbon layer, wherein the material layer is selected from a group consisting of silicon oxide, silicon nitride, silicon oxynitride, silicon carbide, low-k and porous dielectric material.

19. A method of an amorphous carbon layer, comprising:
providing a substrate having a material layer in a processing chamber;
forming a plasma in a deposition gas mixture in the processing chamber;
applying a low frequency and a high frequency RF bias powers at a ratio between about 1:10 and about 10:1 to an electrode disposed in the processing chamber;
forming an amorphous carbon layer on a material layer disposed on a positioned in the processing chamber; and
etching the material layer using the amorphous carbon layer as a hardmask layer.

20. The method of claim 1, wherein the amorphous carbon layer is deposited as a hardmask layer selective to a layer upon which the amorphous carbon layer is disposed.
